(19) United States
(12) Patent Application Publication
(10) Pub. No.: US 2008/0157164 A1
(43) Pub. Date: Jul. 3, 2008

(54) Flash Memory and Method for Fabricating Thereof

(76) Inventor: JI HO HONG, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/924,135

(22) Filed: Oct. 25, 2007

(30) Foreign Application Priority Data
Dec. 27, 2006 (KR) 10-2006-0134816

(51) Int. Cl. H01L 29/788; H01L 21/31

(52) U.S. Cl. 257/316; 438/696; 257/E21.24; 257/E29.3

(57) ABSTRACT

Disclosed are methods for fabricating a flash memory. One method comprises forming an oxide layer on both a gate structure, which includes a floating gate and a control gate, on a cell area and a gate on a periphery area of a semiconductor substrate. An insulating layer having a thickness of 800 Å to 1200 Å can be formed on the oxide layer, and a photoresist pattern that covers the periphery area while exposing the cell area can be formed. The insulating layer formed on the exposed cell area can be wet-etched such that the insulating layer on the cell area has a thickness different from a thickness of the insulating layer on the periphery area. After the photoresist pattern is removed, spacers can be formed by performing reactive-ion etching over an entire surface of the semiconductor substrate.

### CROSS REFERENCE TO RELATED APPLICATION

The present application claims the benefit under 35 U.S.C. §119 of Korean Patent Application No. 10-2006-0134816, filed Dec. 27, 2006, which is hereby incorporated by reference in its entirety.

### BACKGROUND

A flash memory is a nonvolatile memory that does not lose data stored therein even if power is turned off. In addition, flash memory provides a relatively high data processing speed for recording, reading, and deleting data. Accordingly, flash memory is widely used for a Bios of a PC (personal computer), a set-top box, a printer, and a network server in order to store data. Recently, flash memory is extensively used for digital cameras and portable phones.

The size of a structure including a gate that constitutes the flash memory becomes reduced with the change in a technology node. As a result, the margin of a gap-fill process that fills insulating material in order to form an interlayer dielectric layer is gradually reduced.

According to the current technology, in the case of a 0.13 μm technology node flash memory, the gap-fill margin of an interlayer dielectric layer is sufficient. However, in the case of a 90 nm technology node flash memory, the gap-fill margin of an interlayer dielectric layer is very insufficient. Therefore, when filling interlayer insulating material by using a related method, a sufficient space is not ensured between gates, so gap-fill failure such as a void may occur.

Due to such gap-fill failure, interconnections of a drain region are bridged with each other through voids after subsequent processes of forming interconnections, including forming a barrier metal layer, so that a memory device may have a fatal defect.

In order to solve such problems, there has been proposed a method of developing an insulating layer gap-fill process for providing excellent gap-fill characteristics using a new apparatus. However, since the method requires a new up-to-date apparatus, the entire development cost is considerably increased.

Further, there has been proposed a method of reducing an aspect ratio, which is a very important factor in the gap-fill process, by decreasing the thickness or height of a spacer formed on the lateral side of a gate structure on a cell area. In such a case, the gap-fill process can be performed for the cell area without voids, but the thickness or height of the spacer formed on the lateral side of the gate on the periphery area is inevitably reduced. Therefore, breakdown voltage characteristics in the periphery area are deteriorated.

### BRIEF SUMMARY

Embodiments of the present invention provide a flash memory and method for fabricating the same. According to an embodiment, a flash memory device is provided capable of constantly maintaining breakdown voltage characteristics in a periphery area without using a new gap-fill apparatus in a 90 nm technology node.

In order to accomplish the object of the present invention, in an embodiment, there is provided a method for fabricating a flash memory comprising: providing a semiconductor substrate with a gate structure having a floating gate and a control gate on a cell area and a gate on a periphery area; and forming spacers on sidewalls of the gate structure on the cell area and on sidewalls of the gate on the periphery area, wherein the spacers on the sidewalls of the gate structure on the cell area are thinner than the spacers on the sidewalls of the gate on the periphery area.

In one embodiment, the method involves: forming an oxide layer on both a gate structure on a cell area and a gate on a periphery area of a semiconductor substrate; forming an insulating layer having a thickness of 800 Å to 1200 Å on the oxide layer; forming a photoresist pattern that covers the periphery area while exposing the cell area; wet-etching the insulating layer formed on the exposed cell area such that the insulating layer on the cell area has a thickness different from a thickness of the insulating layer on the periphery area; removing the photoresist pattern; and forming spacers by performing reactive-ion etching over an entire surface of the semiconductor substrate.

In another embodiment, the method involves forming an oxide layer on both a gate structure on a cell area and a gate on a periphery area of a semiconductor substrate; sequentially forming a first insulating layer, a nitride layer, and a second insulating layer on the oxide layer; performing a reactive-ion etching process to form insulating layer-nitride-insulating layer spacers on sidewalls of the gate structure and the gate; forming a photoresist pattern on the substrate, including the insulating layer-nitride-insulating layer spacers, exposing the cell area and covering the periphery area; performing a wet-etching process to remove the second insulating layer from the insulating layer-nitride-insulating layer spacers on the cell area; and removing the photoresist pattern.

### BRIEF DESCRIPTION OF THE DRAWINGS

FIGS. 1 to 4 are cross-sectional views showing a method for fabricating a flash device according to an embodiment of the present invention.

FIGS. 5 to 7 are cross-sectional views showing a method for fabricating a flash device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

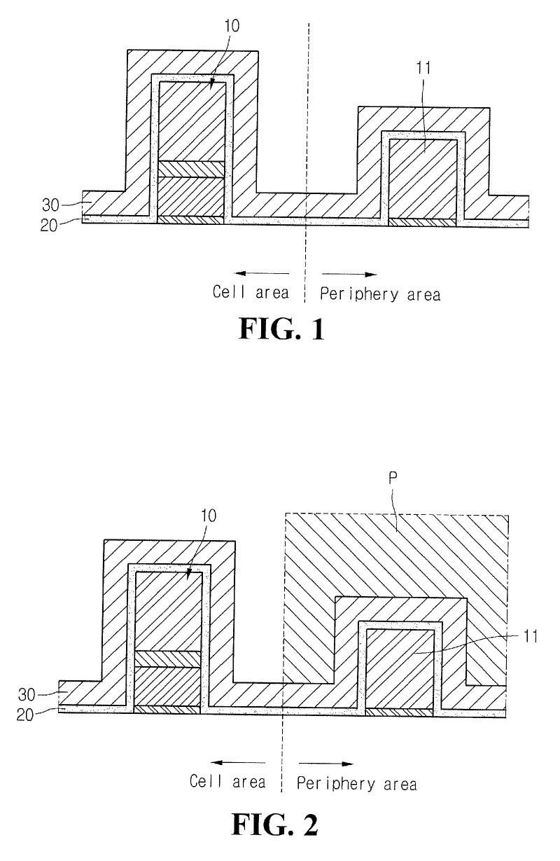

FIGS. 1 to 4 are cross-sectional views showing a method for fabricating a flash device according to a first embodiment.

Referring to FIG. 1, a semiconductor substrate can be defined with a cell area and a periphery area. A gate structure 10 can be formed on the cell area of the semiconductor substrate. The gate structure 10 can include a tunnel oxide layer, a floating gate on the tunnel oxide layer, an oxide-nitride-oxide (ONO) layer on the floating gate, and a control gate on the ONO layer.

The tunnel oxide layer and a gate 11 can be formed on the periphery area of the semiconductor substrate.

An oxide layer 20 can be formed on the gate structure 10 on the cell area and the gate 11 on the periphery area. The oxide layer 20 can include, for example, a high temperature oxide layer and a spacer oxide layer. In a preferred embodiment, the high temperature oxide layer has a thickness of about 70 Å to 80 Å formed at a temperature of about 700° C. to 800° C., and the spacer oxide layer has a thickness of about 50 Å to 70 Å. In one embodiment, the high temperature oxide layer has a thickness of 75 Å and the spacer oxide layer has a thickness of 60 Å.

Then, an insulating layer 30 can be formed on the oxide layer 20. The insulating layer 30 can have a thickness of about 800 Å to 1200 Å. In one embodiment, the insulating layer has a thickness of 1000 Å. The insulating layer 30 may include a TEOS layer. According to an embodiment, the insulating layer, e.g. the TEOS, is formed to be three to five times as thick as a related art insulating layer for forming spacers. Accordingly, the spacers on the cell and periphery areas of the present invention can be formed with different thicknesses through wet etching in the subsequent processes.

Referring to FIG. 2, a photoresist film can be coated on the entire surface of the semiconductor substrate, and then is exposed and developed to form a photoresist pattern P that covers the periphery area while exposing the cell area of the semiconductor substrate.

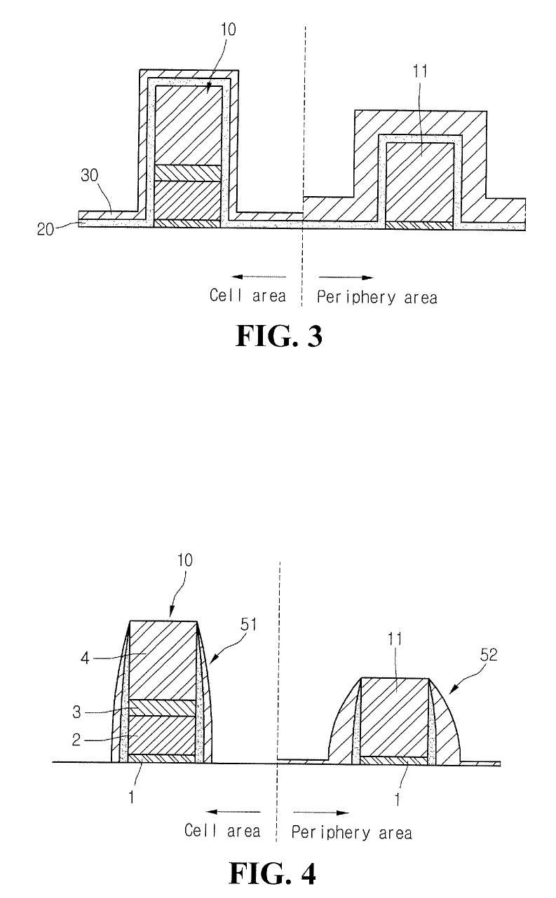

Referring to FIG. 3, a wet etching process can be performed using the photoresist pattern P as an etching mask such that the insulating layer formed on the gate structure 10 on the cell area has a thickness different from that of the insulating layer formed on the gate 11 on the periphery area. Then, the photoresist pattern P is removed.

Referring to FIG. 4, the insulating layers with different thicknesses are etched to form spacers 51 and 52 with different thicknesses on the lateral sides of the gate structure 10 on the cell area and on the lateral sides of the gate 11 on the periphery area, respectively. In a preferred embodiment, dry etching, particularly, RIE (reactive ion etching) is performed to form the spacers 51 and 52.

Then, an interlayer insulating material gap-fill process can be performed for the entire surface of the semiconductor substrate, and subsequent processes known in the art can be performed to form the flash memory.

Accordingly, the spacer on the cell area can have a thin thickness and the spacer on the periphery area can have a thick thickness, so that voids can be inhibited from occurring in the gap-fill process, and the breakdown voltage characteristics in the periphery area can be constantly maintained.

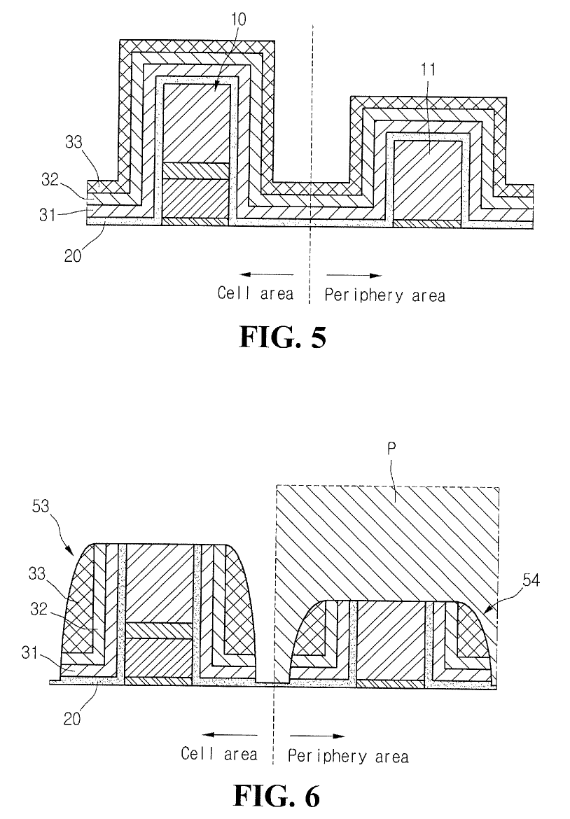

FIGS. 5 to 7 are cross-sectional views showing a method for fabricating a flash device according to a second embodiment.

Referring to FIG. 5, similarly to the first embodiment as described above, a semiconductor substrate can be defined with a cell area and a periphery area. A gate structure 10 can be formed on the cell area of the semiconductor substrate. The gate structure 10 can include a tunnel oxide layer, a floating gate on the tunnel oxide layer, an ONO layer on the floating gate, and a control gate on the ONO layer.

The tunnel oxide layer and a gate 11 can be formed on the periphery area of the semiconductor substrate.

An oxide layer 20 can be formed on the gate structure 10 on the cell area and the gate 1I on the periphery area. The oxide layer 20 can include, for example, a high temperature oxide layer, and a spacer oxide layer. In a preferred embodiment, the high temperature oxide layer has a thickness of about 70 Å to 80 Å and is formed at a temperature of about 700° C. to 800° C. The spacer oxide layer can have a thickness of about 50 Å to 70 Å. In one embodiment, the high temperature oxide layer has a thickness of 75 Å and the spacer oxide layer has a thickness of 60 Å.

Then, a first insulating layer 31, a nitride layer 32, and a second insulating layer 33 can be sequentially formed on the oxide layer 20. The first and second insulating layer 31 and 33 may include a TEOS layer. The first insulating layer 31 may have a thickness of about 150 Å to 250 Å, the nitride layer 32 may have a thickness of about 150 Å to 250 Å, and the second insulating layer 33 may have a thickness of about 500 Å to 700 Å. In one embodiment, the first insulating layer 31 has a thickness of 200 Å, the nitride layer 32 has a thickness of 200 Å, and the second insulating layer 33 has a thickness of 600 Å.

The second insulating layer 33 can have a thickness thicker than that of the first insulating layer 31 and the nitride layer 32, so that a spacer on the periphery area can be thickly formed by employing the second insulating layer 33 as a spacer layer in a subsequent processes, and a PMD (interlayer dielectric layer) gap-fill margin can be sufficiently ensured by removing the second insulating layer 33 from the cell area.

Referring to FIG. 6, the first insulating layer 31, the nitride layer 32 and the second insulating layer 33 can be reactive-ion etched to form spacers 53 and 54. Then, a photoresist film is coated on the entire surface of the semiconductor substrate, and then is exposed and developed to form a photoresist pattern P that covers the periphery area while exposing the cell area.

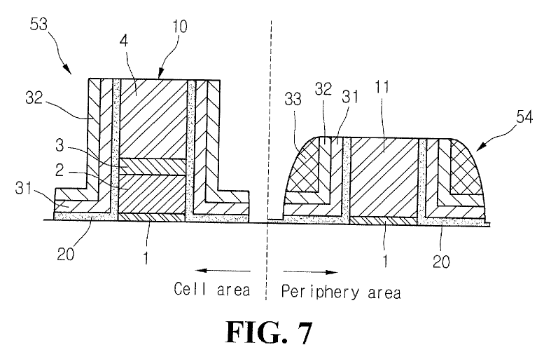

Referring to FIG. 7, the exposed cell area can be wet-etched to remove the second insulating layer 33 on the cell area.

Then, an interlayer insulating material gap-fill process is performed for the entire surface of the semiconductor substrate, and the related subsequent processes are performed to form the flash memory.

Accordingly, the spacer on the cell area can have a thin thickness and the spacer on the periphery area can have a thick thickness, so that voids can be inhibited from occurring in the gap-fill process, and the breakdown voltage characteristics in the periphery area can be constantly maintained.

According to a flash memory fabricated in the first embodiment, referring to FIG. 4, the semiconductor substrate can be defined with the cell area and the periphery area. The tunnel oxide layer 1 is formed on the cell area and the floating gate 2 is formed on the tunnel oxide layer 1. The gate insulating layer 3 is formed on the floating gate 2.

The gate insulating layer 3 may include an ONO layer in which an oxide layer, a nitride layer and an oxide layer are provided. The control gate 4 is formed on the gate insulating layer 3. The tunnel oxide layer 1, the floating gate 2, the gate insulating layer 3 and the control gate 4 are referred to as the gate structure 10.

The first spacer 51 is formed on the lateral sides of the gate structure 10. The first spacer 51 may include an oxide layer and an insulating layer, and the insulating layer, for example, includes a TEOS layer. The insulating layer may have a thickness of about 100 Å to 300 Å. Preferably, the insulating layer has a thickness of 200 Å.

The tunnel oxide layer 1 is formed on the periphery area and the gate 11 is formed on the tunnel oxide layer 1. The gate 11 may include a floating gate.

The second spacer 52 is formed on the lateral sides of the gate 11 on the periphery area. The second spacer 52 may include an oxide layer and an insulating layer, and the insulating layer, for example, includes a TEOS layer. The insulating layer may have a thickness of about 600 Å to 800 Å. Preferably, the insulating layer has a thickness of 700 Å.

The thicknesses of the first and second spacers 51 and 52 may be measured from the lower surfaces thereof.

According to a flash memory fabricated in the second embodiment, referring to FIG. 7, the semiconductor substrate is provided with the cell area and the periphery area. The tunnel oxide layer 1 is formed on the cell area and the floating gate 2 is formed on the tunnel oxide layer 1. The gate insulating layer 3 is formed on the floating gate 2.

The gate insulating layer 3 may include an ONO layer in which an oxide layer, a nitride layer and an oxide layer are provided. The control gate 4 is formed on the gate insulating layer 3. The tunnel oxide layer 1, the floating gate 2, the gate insulating layer 3 and the control gate 4 are referred to as the gate structure 10.

The first spacer 53 is formed on the lateral sides of the gate structure 10. The first spacer 53 may include the oxide layer 20, the nitride layer 32 and the first insulating layer 31. The first insulating layer 31, for example, includes a TEOS layer. The first insulating layer 31 may have a thickness of about 100 Å to 300 Å. Preferably, the first insulating layer 31 has a thickness of 200 Å.

The tunnel oxide layer 1 is formed on the periphery area and the gate 11 is formed on the tunnel oxide layer 1. The gate 11 may include a floating gate.

The second spacer 54 is formed on the lateral sides of the gate 11 on the periphery area. The second spacer 54 may include the oxide layer 20, the first insulating layer 31, the nitride layer 32 and the second insulating layer 33. The first and second insulating layers 31 and 33, for example, include a TEOS layer. The first and second insulating layers 31 and 33 may have a thickness of about 600 Å to 800 Å. Preferably, the first and second insulating layers 31 and 33 have a thickness of 700 Å.

According to the flash memory and the method for fabricating the same of the first and second embodiments as described above, breakdown voltage characteristics in the periphery area can be constantly maintained without using a new gap-fill process apparatus in a 90 nm technology node, so that the electrical characteristics of the flash memory can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a flash memory, comprising:
providing a semiconductor substrate comprising a gate structure on a cell area and a gate on a periphery area, wherein the gate structure comprises a floating gate and a control gate;
forming spacers on sidewalls of the gate structure on the cell area and on sidewalls of the gate on the periphery area, wherein the spacers on the sidewalls of the gate structure on the cell area are thinner than the spacers on the sidewalls of the gate on the periphery area.

2. The method according to claim 1, wherein forming spacers comprises:
forming an oxide layer on the semiconductor substrate, including the gate structure and the gate;
forming an insulating layer on the oxide layer;
forming a photoresist pattern on the insulating layer exposing the cell area and covering the periphery area;
performing a wet-etching process to etch the exposed insulating layer such that the insulating layer on the cell area has a thinner thickness than the insulating layer on the periphery area;
removing the photoresist pattern; and
performing a reactive-ion-etching process to form the spacers on the sidewalls of the gate structure and the gate.

3. The method according to claim 2, wherein the insulating layer is formed to a thickness of about 800 Å to 1200 Å on the oxide layer.

4. The method according to claim 2, wherein the insulating layer comprises a TEOS layer.

5. The method according to claim 1, wherein forming spacers comprises:
forming an oxide layer on the semiconductor substrate including the gate structure and the gate;
forming a first insulating layer on the oxide layer;
forming a nitride layer on the first insulating layer;
forming a second insulating layer on the nitride layer;
performing a reactive-ion etching process to form insulating layer-nitride-insulating layer spacers on sidewalls of the gate structure and the gate;
forming a photoresist pattern on the substrate, including the insulating layer-nitride-insulating layer spacers, exposing the cell area and covering the periphery area;
performing a wet-etching process to remove the second insulating layer from the insulating layer-nitride-insulating layer spacers on the cell area; and
removing the photoresist pattern.

6. The method according to claim 5, wherein the first insulating layer comprises a TEOS layer and the second insulating layer comprises a TEOS layer.

7. The method according to claim 5, wherein the first insulating layer has a thickness of about 150 Å to 250 Å, the nitride layer has a thickness of about 150 Å to 250 Å, and the second insulating layer has a thickness of about 500 Å to 700 Å.

8. A flash memory, comprising:
a semiconductor substrate having a cell area and a periphery area;
a first spacer on a lateral side of a gate structure comprising a floating gate and a control gate on the cell area; and
a second spacer on a lateral side of a gate on the periphery area, wherein the second spacer has a thickness thicker than a thickness of the first spacer.

9. The flash memory according to claim 8, wherein the first spacer has a thickness of about 100 Å to 300 Å and the second spacer has a thickness of about 600 Å to 800 Å.

10. The flash memory according to claim 8, wherein the first spacer comprises a first insulating layer and a nitride layer; and
wherein the second spacer comprises a first insulating layer, a nitride layer, and a second insulating layer.

11. The flash memory according to claim 10, wherein the first insulating layer has a thickness of about 150 Å to 250 Å, the nitride layer has a thickness of about 150 Å to 250 Å, and the second insulating layer has a thickness of about 500 Å to 700 Å.
